(19) United States
(12) Patent Application Publication
(10) Pub. No.: US 2026/0155101 A1
(43) Pub. Date: Jun. 4, 2026

(54) DISPLAY DEVICE

(71) Applicant: LG Display Co., Ltd., Seoul (KR)

(72) Inventors: Young-In JANG, Paju-si (KR); Hye-Mi LEE, Paju-si (KR); So-Yi LEE, Paju-si (KR)

(73) Assignee: LG Display Co., Ltd., Seoul (KR)

(21) Appl. No.: 19/361,729

(22) Filed: Oct. 17, 2025

(30) Foreign Application Priority Data
Dec. 3, 2024 (KR) 10-2024-0177401

(51) Int. Cl. G09G 3/3233; H10H 29/49

(52) U.S. Cl. CPC G09G 3/3233; H10H 29/49; G09G 2300/0426; G09G 2300/0842; G09G 2300/0861; G09G 2310/08; G09G 2320/0238; G09G 2330/021

(57) ABSTRACT

A display device includes a substrate, a first transistor over the substrate and connected to a first power line, a second transistor over the substrate and connected to a second power line, a light-emitting element connected to the first transistor and the second transistor, and a connection element connected to the first power line and the light-emitting element. The connection element may overlap at least a part of the first transistor.

### CROSS-REFERENCE TO RELATED APPLICATION

The present application claims priority to Korean Patent Application No. 10-2024-0177401, filed in the Republic of Korea on Dec. 3, 2024, the entire contents of which are hereby expressly incorporated by reference into the present application.

### BACKGROUND

### Technical Field

The present disclosure relates to a display device and, more particularly, to a display device including a light-emitting element.

### Discussion of the Related Art

As the information society progresses, a demand for different types of display devices increases, and flat panel display devices (FPD), such as liquid crystal display devices and light-emitting diode display devices, have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device can offer various advantages and improved properties. For instance, compared to the liquid crystal display device, because it is self-luminous, the light-emitting diode display device has a wide viewing angle, and since a backlight unit is not required, the light-emitting diode display device has an ultra-thin thickness and light weight. In addition, the light-emitting diode display device is also advantageous in power consumption.

The light-emitting diode display device may include inorganic-based light-emitting elements and organic-based light-emitting elements. The inorganic-based light-emitting elements have relatively excellent stability, fast response characteristics, and high contrast ratios, and micro light-emitting diodes (micro LEDs or μLED) are widely used as the inorganic-based light-emitting elements for high resolution.

However, the inorganic-based light-emitting element may have a lower threshold voltage than the organic-based light-emitting element, so there is a potential problem in that light emission may occur in a black state, thereby resulting in a decrease in image quality.

### SUMMARY

Accordingly, embodiments of the present disclosure are directed to a display device that substantially obviate one or more of the problems due to limitations and disadvantages of the related art.

An aspect of the present disclosure is to provide a display device capable of improving image quality.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device includes a substrate, a first transistor over the substrate and connected to a first power line, a second transistor over the substrate and connected to a second power line, a light-emitting element connected to the first transistor and the second transistor, and a connection element connected to the first power line and the light-emitting element, wherein the connection element overlaps at least a part of the first transistor.

It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure. In the drawings:

FIG. 1 is a schematic plan view of a display device according to one or more example embodiments of the present disclosure;

FIG. 2 is an equivalent circuit diagram for a sub-pixel of a display device according to a first example embodiment of the present disclosure;

FIG. 3 is a timing diagram of a plurality of signals and a plurality of node voltages used to drive a display device according to the first example embodiment of the present disclosure;

FIG. 4 is a schematic plan view of a display device according to the first example embodiment of the present disclosure;

FIG. 5 is a schematic cross-sectional view of a display device according to the first example embodiment of the present disclosure;

FIG. 6 is an equivalent circuit diagram for a sub-pixel of a display device according to a second example embodiment of the present disclosure;

FIG. 7 is a schematic plan view of a display device according to the second example embodiment of the present disclosure; and

FIG. 8 is a schematic cross-sectional view of a display device according to the second example embodiment of the present disclosure.

### DETAILED DESCRIPTION

Advantages and features of the present disclosure and methods for achieving them will be made clear from example embodiments described below in detail with reference to the accompanying drawings. The present disclosure can, however, be implemented in many different forms and should not be construed as being limited to the example embodiments set forth herein, and the example embodiments are provided such that this disclosure will be more thorough and complete and will more fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the example embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure, unless otherwise specified.

Further, in the following description of example embodiments of the present disclosure, where a detailed description of a known related art may unnecessarily obscure a feature or aspect of the present disclosure, the detailed description of such known related art may be omitted herein or may be briefly discussed.

Where terms such as “including,” “having,” “comprising,” and the like are used in this disclosure, other parts can be added unless a more specific term like “only” is used herein.

Further, where a component is expressed as being singular, being plural is included unless otherwise specified.

In analyzing a component, an error range is to be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more specific term like “immediately” or “directly” is used therewith.

In describing a temporal relationship, for example, where a temporal predecessor relationship is described as being “after,” “subsequent,” “next to,” “prior to,” or the like, unless a more specific term like “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner. For example, the term “in contact with,” as used herein, encompasses both “indirect contact” and “direct contact.” Accordingly, where the phrase “A is in contact with B” is used, it implies that other components may be present between A and B, unless explicitly specified as, for example, “A is in direct contact with B.”

Although the terms first, second, and the like may be used to describe various components, these components are not substantially limited by these terms. These terms are used only to refer to one component separately from another component, and not to define any order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in an associated relationship.

Hereinafter, example embodiments of the present disclosure will be described in detail with reference to accompanying drawings.

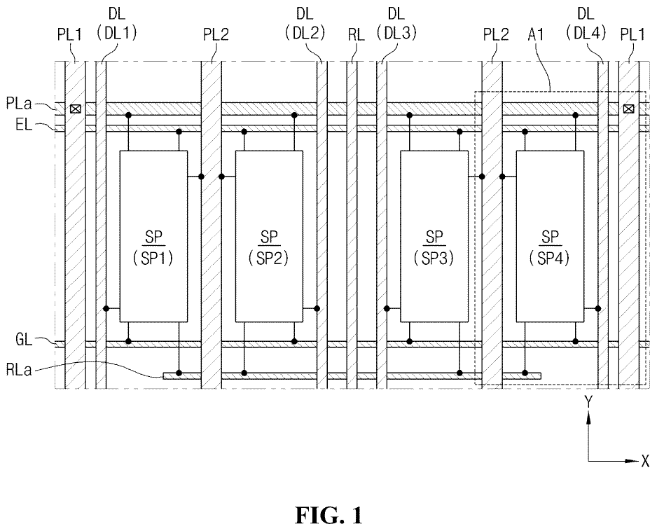

FIG. 1 is a schematic plan view of a display device according to one or more example embodiments of the present disclosure and shows one pixel.

As shown in FIG. 1, in the display device according to one or more example embodiments of the present disclosure, a gate line GL and an emission line EL may extend in a first direction X. A data line DL, a first power line PL1, a second power line PL2, and a reference line RL may extend in a second direction Y and may cross the gate line GL and the emission line EL, thereby defining a plurality of sub-pixels SP. A light-emitting element, a plurality of transistors, and a storage capacitor may be provided in each sub-pixel SP, and this will be described in detail later.

The gate line GL may transmit a gate signal SCAN, and the emission line EL may transmit an emission signal EM. The data line DL may transmit a data voltage Vdata, and the reference line RL may transmit a reference voltage Vref. In addition, the first power line PL1 may be a high potential power line transmitting a high potential voltage VDD, and the second power line PL2 may be a low potential power line transmitting a low potential voltage VSS.

Each sub-pixel SP may be disposed between the gate line GL and the emission line EL in the second direction Y. For example, the gate line GL may be disposed at a lower portion of each sub-pixel SP, and the emission line EL may be disposed at an upper portion of each sub-pixel SP. However, embodiments of the present disclosure are not limited thereto, and the arrangement of the gate line GL and the emission line EL may vary.

One reference line RL may be disposed between two first power lines PL1 in the first direction X, and the second power line PL2 may be disposed between the first power line PL1 and the reference line RL. One data line DL may be disposed between the first power line PL1 and the second power line PL2 and between the second power line PL2 and the reference line RL. That is, one of the first power line PL1, the second power line PL2, and the reference line RL may be disposed between adjacent two data lines DL.

Here, a distance between the data line DL and the second power line PL2 may be greater than a distance between the data line DL and the first power line PL1 or a distance between the data line DL and the reference line RL. Each sub-pixel SP may be disposed between the data line DL and the second power line PL2.

The data line DL may include first, second, third, and fourth data lines DL1, DL2, DL3, and DL4. The first data line DL1 may be disposed between the first power line PL1 and the second power line PL2. The second data line DL2 may be disposed between the second power line PL2 and the reference line RL. The third data line DL3 may be disposed between the reference line RL and one other second power line PL2. The fourth data line DL4 may be disposed between the other second power line PL2 and another first power line PL1.

In addition, an auxiliary power line PLa and an auxiliary reference line RLa may extend in the first direction X. The gate line GL and the emission line EL may be disposed between the auxiliary power line PLa and the auxiliary reference line RLa. In this case, the auxiliary power line PLa may be disposed adjacent to the emission line EL, and the auxiliary reference line RLa may be disposed adjacent to the gate line GL. However, embodiments of the present disclosure are not limited thereto, and the arrangement of the auxiliary power line PLa and the auxiliary reference line RLa may vary.

The auxiliary power line PLa may cross and overlap the first, second, third, and fourth data lines DL1, DL2, DL3, and DL4, the first power line PL1, the second power line PL2, and the reference line RL and may be connected to the first power line PL1 to supply the high potential voltage VDD to each sub-pixel SP.

The auxiliary reference line RLa may cross and overlap the second and third data lines DL2 and DL3, the second power line PL2, and the reference line RL and may be connected to the reference line RL to supply the reference voltage Vref to each sub-pixel SP. The auxiliary reference line RLa may be spaced apart from the first and fourth data lines DL1 and DL4 and the first power line PL1.

Each sub-pixel SP may have a substantially rectangular shape. However, embodiments of the present disclosure are not limited thereto, and the shape of each sub-pixel SP may vary.

The plurality of sub-pixels SP may constitute one pixel. For example, one pixel may include first, second, third, and fourth sub-pixels SP1, SP2, SP3, and SP4. The first, second, third, and fourth sub-pixels SP1, SP2, SP3, and SP4 may be sequentially arranged in the first direction X. Here, the first sub-pixel SP1 and the second sub-pixel SP2 may be red sub-pixels, the third sub-pixel SP3 may be a green sub-pixel, and the fourth sub-pixel SP4 may be a blue sub-pixel. However, embodiments of the present disclosure are not limited thereto, and the number and arrangement of the sub-pixels SP included in one pixel may vary.

Two sub-pixels SP adjacent to each other in the first direction X may be symmetrical. For example, the first sub-pixel SP1 and the second sub-pixel SP2 may be symmetrical with the third and fourth sub-pixels SP3 and SP4 with respect to the reference line RL. The first sub-pixel SP1 may be symmetrical with the second sub-pixel SP2 with respect to the second power line PL2, and the third sub-pixel SP3 may be symmetrical with the fourth sub-pixel SP4 with respect to another second power line PL2.

The configuration of the sub-pixel of the display device according to example embodiments of the present disclosure will be described in detail with reference to accompanying drawings.

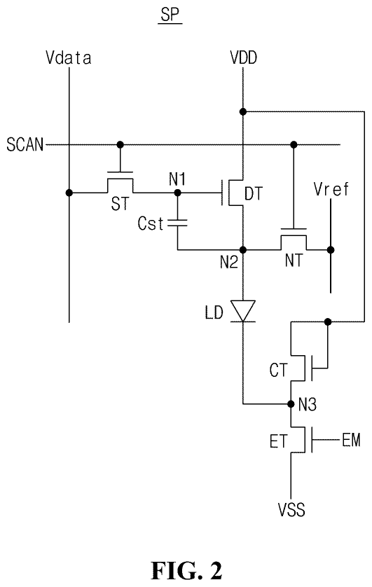

FIG. 2 is an equivalent circuit diagram for a sub-pixel of a display device according to a first example embodiment of the present disclosure and will be described with reference to FIG. 1 together.

In FIG. 2, one sub-pixel SP of the display device according to the first example embodiment of the present disclosure may include a switching transistor ST, a driving transistor DT, a sensing transistor NT, a storage capacitor Cst, and a light-emitting diode LD. The sub-pixel SP may have substantially a 3T1C structure including three transistors and one storage capacitor as a basic configuration, but embodiments of the present disclosure are not limited thereto. The number of the transistors and capacitor may vary. In addition, the sub-pixel SP may further include an emission transistor ET and a connection transistor CT.

For example, the switching transistor ST, the driving transistor DT, the sensing transistor NT, the emission transistor ET, and the connection transistor CT may be n-type transistors. However, embodiments of the present disclosure are not limited thereto. In other embodiments, the switching transistor ST, the driving transistor DT, the sensing transistor NT, the emission transistor ET, and the connection transistor CT may be p-type transistors.

The switching transistor ST may be switched according to the gate signal SCAN and may transmit the data voltage Vdata to a first node N1. Specifically, a gate of the switching transistor ST may be connected to the gate line GL and may be supplied with the gate signal SCAN. A source of the switching transistor ST may be connected to the data line DL and may be supplied with the data voltage Vdata. A drain of the switching transistor ST may be connected to the first node N1.

The driving transistor DT may be switched according to a voltage of the first node N1 and may transmit the high potential voltage VDD to a second node N2. Specifically, a gate of the driving transistor DT may be connected to the first node N1. A drain of the driving transistor DT may be connected to the first power line PL1 and may be supplied with the high potential voltage VDD. A source of the driving transistor DT may be connected to the second node N2.

The sensing transistor NT may be switched according to the gate signal SCAN and may transmit the reference voltage Vref to the second node N2 or transmit a voltage of the second node N2 to the reference line RL. Specifically, a gate of the sensing transistor NT may be connected to the gate line GL and may be supplied with the gate signal SCAN. A source of the sensing transistor NT may be connected to the reference line RL and may be supplied with the reference voltage Vref or transmit the voltage of the second node N2 to the reference line RL. A drain of the sensing transistor NT may be connected to the second node N2.

The storage capacitor Cst may maintain the data voltage Vdata supplied to the first node N1 for a frame and may store a threshold voltage Vth of the driving transistor DT. First and second capacitor electrodes of the storage capacitor Cst may be connected to the first node N1 and the second node N2, respectively.

The light-emitting diode LD may emit light with luminance proportional to a current of the driving transistor DT. Specifically, an anode of the light-emitting diode LD may be connected to the second node N2, and a cathode of the light-emitting diode LD may be connected to a third node N3.

In addition, the emission transistor ET may be switched according to the emission signal EM and may transmit the low potential voltage VSS to the third node N3. Specifically, a gate of the emission transistor ET may be connected to the emission line EL and may be supplied with the emission signal EM. A source of the emission transistor ET may be connected to the second power line PL2 and may be supplied with the low potential voltage VSS. A drain of the emission transistor ET may be connected to the third node N3.

The connection transistor CT may be a connection element for connecting the third node N3 and the first power line PL1 and may be a diode-type transistor in which a gate and a drain are connected. The connection transistor CT may be switched according to the high potential voltage VDD and may transmit the high potential voltage VDD to the third node N3. Specifically, the gate and the drain of the connection transistor CT may be connected to the first power line PL1 and may be supplied with the high potential voltage VDD. A source of the connection transistor CT may be connected to the third node N3.

The gate of the driving transistor DT, the drain of the switching transistor ST, and the first capacitor electrode of the storage capacitor Cst may constitute the first node N1. The source of the driving transistor DT, the drain of the sensing transistor NT, the second capacitor electrode of the storage capacitor Cst, and the anode of the light-emitting diode LD may constitute the second node N2. The cathode of the light-emitting element LD, the drain of the emission transistor ET, and the source of the connection transistor CT may constitute the third node N3.

As such, in the display device according to the first example embodiment of the present disclosure, by providing the connection transistor CT as the connection element and forming a voltage path, the cathode voltage of the light-emitting diode LD, i.e., the voltage of the third node N3 can be controlled. Accordingly, the light-emitting diode LD can be prevented or suppressed from emitting light in a black state.

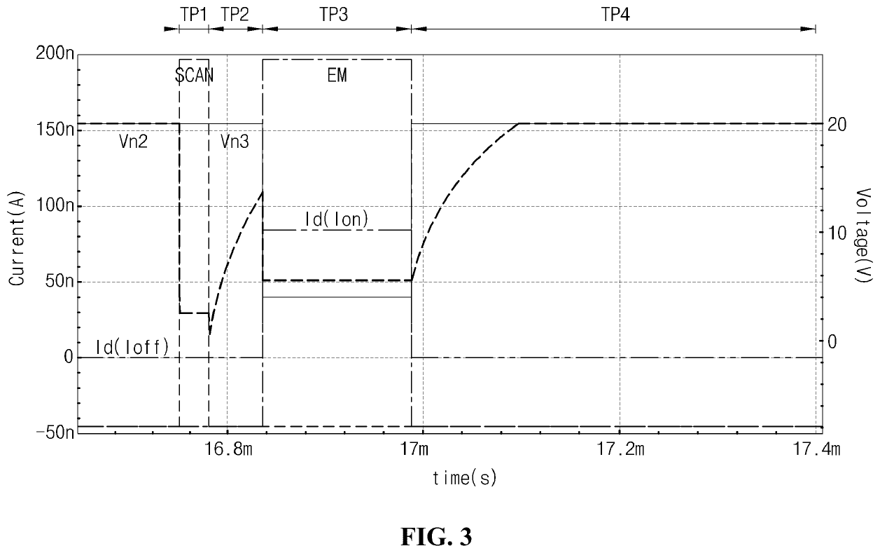

A driving operation of the display device according to the first example embodiment of the present disclosure will be described with reference to FIG. 3.

FIG. 3 is a timing diagram of a plurality of signals and a plurality of node voltages used to drive the display device according to the first example embodiment of the present disclosure and will be described with reference to FIG. 2 together.

As shown in FIG. 3, in the display device according to the first example embodiment of the present disclosure, one frame may include first, second, third, and fourth sections TP1, TP2, TP3, and TP4.

The first section TP1 may be a writing section. In the first section TP1, the gate signal SCAN may have a high level, and the emission signal EM may have a low level.

Accordingly, the switching transistor ST and the sensing transistor NT may be turned on, and the emission transistor ET may be turned off, so that the data voltage Vdata and the reference voltage Vref may be stored in the storage capacitor Cst.

Here, the first node N1 may be charged with the data voltage Vdata, the second node N2 may be charged with the reference voltage Vref, and the third node N3 may be charged with the high potential voltage VDD.

In this case, a voltage Vn2 of the second node N2 may be lower than a voltage Vn3 of the third node N3, and a reverse bias voltage may be applied to the light-emitting diode LD. Therefore, no current Ioff may flow through the light-emitting diode LD, and the light-emitting diode LD may not emit light.

Next, the second section TP2 may be a stabilizing section. In the second section TP2, the gate signal SCAN and the emission signal EM may have low levels.

Accordingly, the switching transistor ST, the sensing transistor NT, and the emission transistor ET may be turned off, so that the first node N1 and the second node N2 may be floating. Electric charges may be accumulated in the second node N2 by a current flowing through the driving transistor DT, and thus the voltage Vn2 of the second node N2 may increase.

In this case, the increased voltage Vn2 of the second node N2 may be lower than the voltage Vn3 of the third node N3 charged with the high potential voltage VDD, and a reverse bias voltage may be applied to the light-emitting diode LD. Therefore, no current Ioff may flow through the light-emitting diode LD, and the light-emitting diode LD may not emit light.

Next, the third section TP3 may be an emission section. In the third section TP3, the gate signal SCAN may have a low level, and the emission signal EM may have a high level.

Accordingly, the switching transistor ST and the sensing transistor NT may be turned off, and the emission transistor ET may be turned on, so that the third node N3 may be charged with the low potential voltage VSS.

In this case, the voltage Vn3 of the third node N3 charged with the low potential voltage VSS may be lower than the voltage Vn2 of the second node N2, and a forward bias voltage may be applied to the light-emitting diode LD. Therefore, a current Ion may flow through the light-emitting diode LD, and the light-emitting diode LD may emit light.

Next, the fourth section TP4 may be a non-emission section. In the fourth section TP4, the gate signal SCAN and the emission signal EM may have the low levels.

Accordingly, the switching transistor ST, the sensing transistor NT, and the emission transistor ET may be turned off, so that the first node N1 and the second node N2 may be floating. Electric charges may be accumulated in the second node N2 by the current flowing through the driving transistor DT, and thus the voltage Vn2 of the second node N2 may increase. The increase in the voltage Vn2 of the second node N2 may continue until the driving transistor DT is turned off.

In this case, the third node N3 may be charged with the high potential voltage VDD. The increased voltage Vn2 of the second node N2 may be lower than or equal to the voltage Vn3 of the third node N3. Accordingly, a reverse bias voltage or no bias voltage may be applied to the light-emitting diode LD, so that no current Ioff may flow through the light-emitting diode LD and the light-emitting diode LD may not emit light.

As such, in the display device according to the first example embodiment of the present disclosure, by making the voltage Vn3 of the third node N3, which is the voltage of the cathode of the light-emitting diode LD, higher than or equal to the voltage Vn2 of the second node N2, the light-emitting diode LD may be prevented or suppressed from emitting light in the first, second, and fourth sections TP1, TP2, and TP4 except for the third section TP3, which is the emission section. Accordingly, by preventing or suppressing light emission in the black state, a contrast ratio of the display device may be increased, and image quality of the display device may be improved.

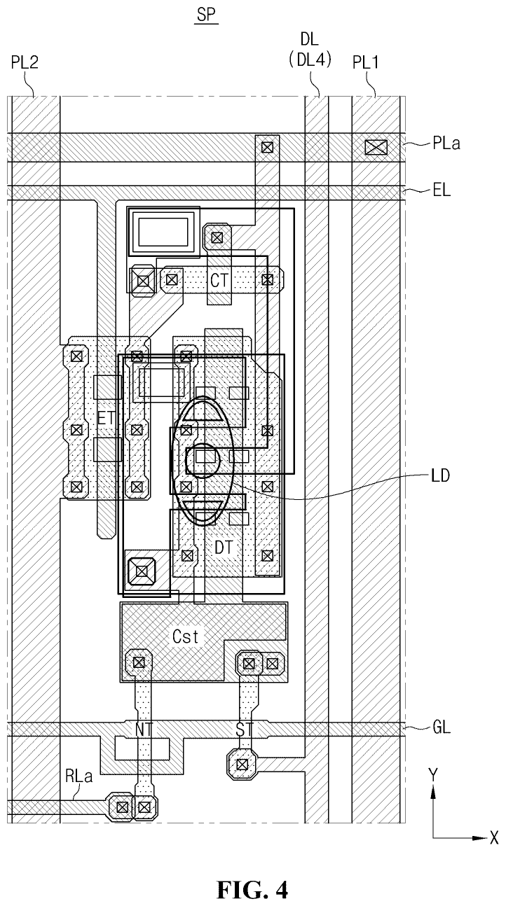

A planar configuration of the display device according to the first example embodiment of the present disclosure will be described with reference to FIG. 4.

FIG. 4 is a schematic plan view of a display device according to the first example embodiment of the present disclosure and shows one sub-pixel, which corresponds to the area A1 of FIG. 1.

In FIG. 4, the gate line GL and the emission line EL of the first direction X may cross the first power line PL1, the second power line PL2, and the data line DL of the second direction Y to define the sub-pixel SP. The switching transistor ST, the driving transistor DT, the sensing transistor NT, the emission transistor ET, the connection transistor CT, the storage capacitor Cst, and the light-emitting diode LD may be provided in the sub-pixel SP.

In the first direction X, the driving transistor DT and the emission transistor ET may be disposed adjacent to each other, and the switching transistor ST and the sensing transistor NT may be disposed adjacent to each other.

In the second direction Y, the storage capacitor Cst may be disposed between the driving and emission transistors DT and ET and the switching and sensing transistors ST and NT, and the connection transistor CT may be disposed between the driving and emission transistors DT and ET and the emission line EL.

Meanwhile, the light-emitting diode LD may be disposed to overlap the driving transistor DT.

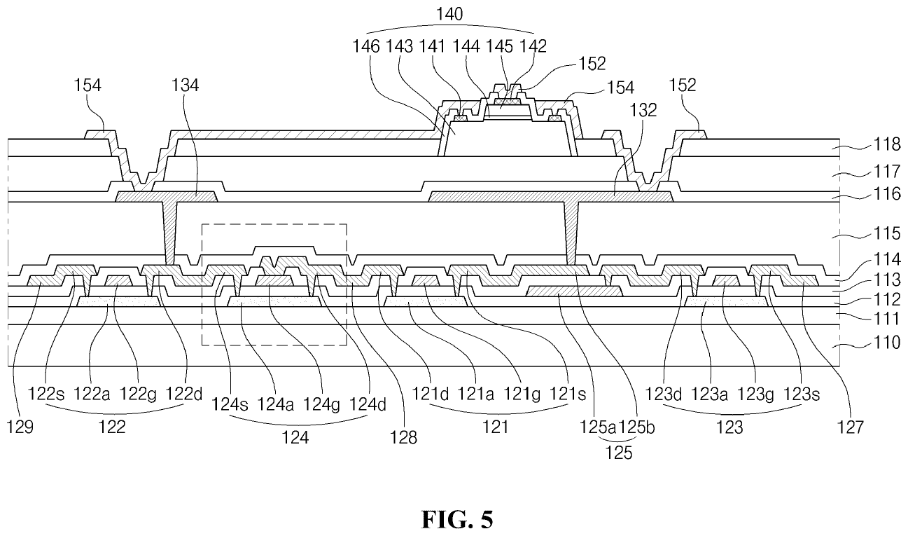

A cross-sectional configuration of the display device according to the first example embodiment of the present disclosure will be described in detail with reference to FIG. 5.

FIG. 5 is a schematic cross-sectional view of a display device according to the first example embodiment of the present disclosure and shows one sub-pixel.

In FIG. 5, the display device according to the first example embodiment of the present disclosure may include first, second, third, and fourth transistors 121, 122, 123, and 124, a capacitor 125, and a light-emitting element 140 on a substrate 110. The light-emitting element 140 may be electrically connected to the first transistor 121 and the second transistor 122. The first transistor 121 may be electrically connected to the capacitor 125 and the third transistor 123 and electrically connected to the fourth transistor 124. The second transistor 122 may be electrically connected to the fourth transistor 124.

Specifically, a buffer layer 111 may be provided on the substrate 110. The substrate 110 may be a glass substrate or a plastic substrate. For example, polyimide can be used for the plastic substrate, but embodiments of the present disclosure are not limited thereto.

The buffer layer 111 may be disposed substantially all over the substrate 110. The buffer layer 111 may be formed as a single layer or multiple layers of an inorganic insulating material. For example, the inorganic insulating material of the buffer layer 111 may include silicon nitride (SiNₓ), silicon oxide (SiOₓ), or silicon oxynitride (SiON).

Meanwhile, although not shown in the figure, a light-shielding layer may be provided between the substrate 110 and the buffer layer 111. The light-shielding layer may overlap the first transistor 121.

First, second, third, and fourth active layers 121a, 122a, 123a, and 124a may be provided on the buffer layer 111. Each of the first, second, third, and fourth active layers 121a, 122a, 123a, and 124a may include a channel region at its central part and source and drain regions at both sides of the channel region. The first, second, third, and fourth active layers 121a, 122a, 123a, and 124a may be formed of an oxide semiconductor material. Alternatively, the first, second, third, and fourth active layers 121a, 122a, 123a, and 124a may be formed of polycrystalline silicon, and in this case, both ends of each of the first, second, third, and fourth active layers 121a, 122a, 123a, and 124a may be doped with impurities.

A gate insulation layer 112 may be provided on the first, second, third, and fourth active layers 121a, 122a, 123a, and 124a and the buffer layer 111. The gate insulation layer 112 may be disposed substantially all over the substrate 110. The gate insulation layer 112 may be formed as a single layer or multiple layers of an inorganic insulating material. For example, the inorganic insulating material of the gate insulation layer 112 may include silicon nitride (SiNₓ), silicon oxide (SiOₓ), or silicon oxynitride (SiON).

First, second, third, and fourth gate electrodes 121g, 122g, 123g, and 124g and a first capacitor electrode 125a may be formed on the gate insulation layer 112. The first, second, third, and fourth gate electrodes 121g, 122g, 123g, and 124g may overlap the first, second, third, and fourth active layers 121a, 122a, 123a, and 124a, respectively. The first, second, third, and fourth gate electrodes 121g, 122g, 123g, and 124g may be disposed to correspond to the central parts of the first, second, third, and fourth active layers 121a, 122a, 123a, and 124a, respectively.

The first, second, third, and fourth gate electrodes 121g, 122g, 123g, and 124g and the first capacitor electrode 125a may be formed of a conductive material such as metal. For example, the first, second, third, and fourth gate electrodes 121g, 122g, 123g, and 124g and the first capacitor electrode 125a may be formed of one or more of: aluminum (Al), copper (Cu), molybdenum (Mo), titanium (Ti), chromium (Cr), nickel (Ni), tungsten (W), and an alloy thereof. The first, second, third, and fourth gate electrodes 121g, 122g, 123g, and 124g and the first capacitor electrode 125a may have a single-layered structure or a multiple-layered structure.

An interlayer insulation layer 113 may be provided on the first, second, third, and fourth gate electrodes 121g, 122g, 123g, and 124g and the first capacitor electrode 125a. The interlayer insulation layer 113 may be disposed substantially all over the substrate 110. The interlayer insulation layer 113 may be formed as a single layer or multiple layers of an inorganic insulating material. For example, the inorganic insulating material of the interlayer insulation layer 113 may include silicon nitride (SiNₓ), silicon oxide (SiOₓ), or silicon oxynitride (SiON).

First, second, third, and fourth source electrodes 121s, 122s, 123s, and 124s, first, second, third, and fourth drain electrodes 121d, 122d, 123d, and 124d, a second capacitor electrode 125b, a first line 127, a second line 128, and a third line 129 may be provided on the interlayer insulation layer 113.

The first, second, third, and fourth source electrodes 121s, 122s, 123s, and 124s, the first, second, third, and fourth drain electrodes 121d, 122d, 123d, and 124d, the second capacitor electrode 125b, the first line 127, the second line 128, and the third line 129 may be formed of a conductive material such as metal. For example, the first, second, third, and fourth source electrodes 121s, 122s, 123s, and 124s, the first, second, third, and fourth drain electrodes 121d, 122d, 123d, and 124d, the second capacitor electrode 125b, the first line 127, the second line 128, and the third line 129 may be formed of one or more of: aluminum (Al), copper (Cu), molybdenum (Mo), titanium (Ti), chromium (Cr), nickel (Ni), tungsten (W), and an alloy thereof. The first, second, third, and fourth source electrodes 121s, 122s, 123s, and 124s, the first, second, third, and fourth drain electrodes 121d, 122d, 123d, and 124d, the second capacitor electrode 125b, the first line 127, the second line 128, and the third line 129 may have a single-layered structure or a multiple-layered structure.

The first source electrode 121s and the first drain electrode 121d may be in contact with the both ends of the first active layer 121a through contact holes provided in the gate insulation layer 112 and the interlayer insulation layer 113, respectively. The second source electrode 122s and the second drain electrode 122d may be in contact with the both ends of the second active layer 122a through contact holes provided in the gate insulation layer 112 and the interlayer insulation layer 113, respectively. The third source electrode 123s and the third drain electrode 123d may be in contact with the both ends of the third active layer 123a through contact holes provided in the gate insulation layer 112 and the interlayer insulation layer 113, respectively. In addition, the fourth source electrode 124s and the fourth drain electrode 124d may be in contact with the both ends of the fourth active layer 124a through contact holes provided in the gate insulation layer 112 and the interlayer insulation layer 113, respectively, and the fourth drain electrode 124d may be in contact with the fourth gate electrode 124g through a contact hole provided in the interlayer insulation layer 113. The second capacitor electrode 125b may overlap the first capacitor electrode 125a.

The first source electrode 121s may be connected to the second capacitor electrode 125b, and the first drain electrode 121d may be connected to the second line 128. The second source electrode 122s may be connected to the third line 129, and the second drain electrode 122d may be connected to the fourth source electrode 124s. The third source electrode 123s may be connected to the first line 127, and the third drain electrode 123d may be connected to the first capacitor electrode 125a through a contact hole provided in the gate insulation layer 112. The fourth source electrode 124s may be connected to the second drain electrode 122d, and the fourth drain electrode 124d may be connected to the second line 128.

The first active layer 121a, the first gate electrode 121g, the first source electrode 121s, and the first drain electrode 121d may constitute the first transistor 121. The second active layer 122a, the second gate electrode 122g, the second source electrode 122s, and the second drain electrode 122d may constitute the second transistor 122. The third active layer 123a, the third gate electrode 123g, the third source electrode 123s, and the third drain electrode 123d may constitute the third transistor 123. The fourth active layer 124a, the fourth gate electrode 124g, the fourth source electrode 124s, and the fourth drain electrode 124d may constitute the fourth transistor 124.

The first capacitor electrode 125a and the second capacitor electrode 125b may constitute the capacitor 125 with the interlayer insulation layer 113 interposed therebetween as a dielectric.

The first transistor 121 may be the driving transistor DT of FIG. 2, the second transistor 122 may be the emission transistor ET of FIG. 2, the third transistor 123 may be the switching transistor ST of FIG. 2, the fourth transistor 124 may be the connection transistor CT, and the capacitor 125 may be the storage capacitor Cst.

In addition, the first line 127 may be the data line DL of FIG. 4, the second line 128 may be the first power line PL1 of FIG. 4 supplying the high potential voltage VDD, and the third line 129 may be the second power line PL2 of FIG. 4 supplying the low potential voltage VSS. However, embodiments of the present disclosure are not limited thereto. In other embodiments, the second line 128 may be the first power line PL1 supplying the low potential voltage VSS, and the third line 129 may be the second power line PL2 supplying the high potential voltage VDD.

Meanwhile, the sensing transistor NT of FIG. 2 may be further provided on the substrate 110 and may have substantially the same as the first, second, and third transistors 121, 122, and 123.

Next, a first passivation layer 114 may be provided on the first, second, third, and fourth source electrodes 121s, 122s, 123s, and 124s, the first, second, third, and fourth drain electrodes 121d, 122d, 123d, and 124d, the second capacitor electrode 125b, the first line 127, the second line 128, and the third line 129. The first passivation layer 114 may be disposed substantially all over the substrate 110. The first passivation layer 114 may be formed as a single layer or multiple layers of an inorganic insulating material. For example, the inorganic insulating material of the first passivation layer 114 may include silicon nitride (SiNₓ), silicon oxide (SiOₓ), or silicon oxynitride (SiON). The first passivation layer 114 may be omitted.

An overcoat layer 115 may be provided on the first passivation layer 114. The overcoat layer 115 may be disposed substantially all over the substrate 110. The overcoat layer 115 may eliminate a step difference due to the layers thereunder and may have a substantially flat top surface. The overcoat layer 115 may be formed of an organic insulating material such as photosensitive acrylic polymer (photo acryl).

A reflection electrode 132 and a connection electrode 134 may be provided on the overcoat layer 115. The reflection electrode 132 and the connection electrode 134 may be formed of a metal having relatively high reflectance. For example, the reflection electrode 132 and the connection electrode 134 may be formed of aluminum (Al), silver (Ag), or chromium (Cr).

The reflection electrode 132 may partially overlap the first transistor 121 and the capacitor 125. The reflection electrode 132 may be electrically connected to the first transistor 121 and the capacitor 125 through a contact hole provided in the first passivation layer 114 and the overcoat layer 115. In this case, the reflection electrode 132 may be in contact with the second capacitor electrode 125b through the contact hole, but embodiments of the present disclosure are not limited thereto. Alternatively, the reflection electrode 132 may be in contact with the first source electrode 121s.

The connection electrode 134 may partially overlap the second transistor 122 and the fourth transistor 124. The connection electrode 134 may be electrically connected to the second transistor 122 and the fourth transistor 124 through a contact hole provided in the first passivation layer 114 and the overcoat layer 115. In this case, the connection electrode 134 may be in contact with the second drain electrode 122d through the contact hole, but embodiments of the present disclosure are not limited thereto. Alternatively, the connection electrode 134 may be in contact with the fourth source electrode 124s.

A second passivation layer 116 may be provided on the reflection electrode 132 and the connection electrode 134. The second passivation layer 116 may be disposed substantially all over the substrate 110. The second passivation layer 116 may be formed as a single layer or multiple layers of an inorganic insulating material. For example, the inorganic insulating material of the second passivation layer 116 may include silicon nitride (SiNₓ), silicon oxide (SiOₓ), or silicon oxynitride (SiON). The second passivation layer 116 may be omitted.

An adhesive layer 117 may be provided on the second passivation layer 116. The adhesive layer 117 may be disposed substantially all over the substrate 110 and may fix the light-emitting element 140 that is transferred thereon.

The adhesive layer 117 may have a substantially flat top surface. The adhesive layer 117 may be formed of an organic insulating material such as a photocurable adhesive material that is cured by light and may have adhesion. For example, the adhesive layer 117 may be formed of photosensitive acrylic polymer (photo acryl). However, embodiments of the present disclosure are not limited thereto. Alternatively, the adhesive layer 117 may be formed of one of a polyimide (PI) resin, an epoxy resin, a urethane resin, and a polydimethylsiloxane (PDMS) resin.

The light-emitting element 140 may be provided on the adhesive layer 117. The light-emitting element 140 may overlap the reflection electrode 132. In addition, the light-emitting element 140 may partially overlap the first transistor 121 and the capacitor 125.

The light-emitting element 140 may be provided in the form of a micro light-emitting diode chip (micro LED chip or μLED chip) including an n-electrode, an n-type layer, an active layer, a p-type layer, and a p-electrode. The light-emitting element 140 may have a lateral structure in which the n-electrode and the p-electrode are provided on the same side (for example, a side opposite to another side facing the substrate 110) and light is emitted through the same side provided with the n-electrode and the p-electrode.

However, embodiments of the present disclosure are not limited thereto. In other embodiments, the light-emitting element 140 may have a flip-chip structure in which the n-electrode and the p-electrode are provided on the same side (for example, a side facing the substrate 110) and light is emitted through another side opposite to the same side provided with the n-electrode and the p-electrode or a vertical structure in which the n-electrode and the p-electrode are provided on opposite sides, respectively.

The light-emitting element 140 may be the light-emitting diode LD of FIG. 2 and may include a first element electrode 141, a second element electrode 142, a light-emitting structure 143, 144, and 145, and a protection layer 146.

The first element electrode 141 and the second element electrode 142 may be provided on the light-emitting structure 143, 144, and 145 and may be spaced apart from each other. The first element electrode 141 and the second element electrode 142 may be disposed at different heights. For example, the second element electrode 142 may be disposed higher than the first element electrode 141.

The first element electrode 141 may be provided at opposite sides of the second element electrode 142. That is, the second element electrode 142 may be disposed between two portions of the first element electrode 141. In this case, the first element electrode 141 may surround the second element electrode 142. However, embodiments of the present disclosure are not limited thereto. In other embodiments, the first element electrode 141 may be provided at one side of the second element electrode 142.

Here, the first element electrode 141 may be an n-electrode, and the second element electrode 142 may be a p-electrode. The first element electrode 141 may be a cathode, and the second element electrode 142 may be an anode.

However, embodiments of the present disclosure are not limited thereto. Alternatively, in other embodiments, the first element electrode 141 may be a p-electrode, and the second element electrode 142 may be an n-electrode.

The first element electrode 141 and the second element electrode 142 may be formed of a conductive material. For example, the first element electrode 141 and the second element electrode 142 may be formed of a transparent conductive material such as indium tin oxide (ITO) or indium zinc oxide (IZO) or an opaque conductive material such as titanium (Ti), gold (Au), silver (Ag), copper (Cu), or an alloy thereof. However, embodiments of the present disclosure are not limited thereto.

The light-emitting structure 143, 144, and 145 may include a first element layer 143, a light-emitting layer 144, and a second element layer 145. The light-emitting layer 144 may be disposed between the first element layer 143 and the second element layer 145.

The light-emitting layer 144 and the second element layer 145 may be disposed on the first element layer 143 and may correspond to a central part of the first element layer 143. The light-emitting layer 144 and the second element layer 145 may have a smaller width and area than the first element layer 143 to partially expose a top surface of the first element layer 143. The first element electrode 141 may be disposed on the exposed top surface of the first element layer 143, and the second element electrode 142 may be disposed on the second element layer 145.

The first element layer 143 and the second element layer 145 may be formed by doping n-type or p-type impurities into a semiconductor material. For example, the first element layer 143 and the second element layer 145 may be formed by doping n-type or p-type impurities into gallium nitride (GaN), indium aluminum phosphide (InAlP), or gallium arsenide (GaAs). In addition, for example, the n-type impurities may be silicon (Si), germanium (Ge), or indium (Sn), and the p-type impurities may be magnesium (Mg), zinc (Zn), or beryllium (Be). However, embodiments of the present disclosure are not limited thereto.

The light-emitting layer 144 may receive electrons and holes from the first element layer 143 and the second element layer 145, respectively, and emit light. The light-emitting layer 144 may be formed of a single quantum well (SQW) structure or a multi quantum well (MQW) structure. For example, the light-emitting layer 144 may be formed of indium gallium nitride (InGaN) or gallium nitride (GaN), but is not limited thereto.

The protection layer 146 may be provided with the first element electrode 141, the second element electrode 142, and the light-emitting structure 143, 144, and 145. The protection layer 146 may cover and protect the first element electrode 141, the second element electrode 142, and the light-emitting structure 143, 144, and 145 and may partially expose top surfaces of the first element electrode 141 and the second element electrode 142.

The protection layer 146 may be formed as a single layer or multiple layers of an inorganic insulating material. The inorganic insulating material of the protection layer 146 may include silicon nitride (SiNₓ), silicon oxide (SiOₓ), or silicon oxynitride (SiON).

Next, a planarization layer 118 may be provided on the light-emitting element 140 and the adhesive layer 117. The planarization layer 118 may be disposed substantially all over the substrate 110.

The planarization layer 118 may surround a portion of a side surface of the light-emitting element 140 and may fix and protect the light-emitting element 140. A thickness of the planarization layer 118 may be smaller than a thickness of the light-emitting element 140 and also smaller than a thickness of the first element layer 143. A top surface of the planarization layer 118 may be disposed lower than the first element electrode 141 and the second element electrode 142 to thereby expose the first element electrode 141 and the second element electrode 142.

The planarization layer 118 may be formed of an organic insulating material such as photosensitive acrylic polymer (photo acryl), for example and may have a substantially flat top surface.

A first contact electrode 152 and a second contact electrode 154 may be provided on the planarization layer 118 and the light-emitting element 140.

The first contact electrode 152 may overlap the second element electrode 142 of the light-emitting element 140 and may be in contact with the second element electrode 142. In addition, the first contact electrode 152 may overlap the reflection electrode 132 and may be in contact with and electrically connected to the reflection electrode 132 through a contact hole provided in the second passivation layer 116, the adhesive layer 117, and the planarization layer 118.

Accordingly, the first contact electrode 152 may be electrically connected to the first source electrode 121s of the first transistor 121 and the second capacitor electrode 125b of the capacitor 125 through the reflection electrode 132. The second element electrode 142 of the light-emitting element 140 may be electrically connected to the first source electrode 121s of the first transistor 121 and the second capacitor electrode 125b of the capacitor 125 through the first contact electrode 152 and the reflection electrode 132.

The second contact electrode 154 may overlap the first element electrode 141 of the light-emitting element 140 and may be in contact with the first element electrode 141. In addition, the second contact electrode 154 may overlap the connection electrode 134 and may be in contact with and electrically connected to the connection electrode 134 through a contact hole provided in the second passivation layer 116, the adhesive layer 117, and the planarization layer 118.

Accordingly, the second contact electrode 154 may be electrically connected to the second drain electrode 122d of the second transistor 122 and the fourth source electrode 124s of the fourth transistor 124 through the connection electrode 134. The first element electrode 141 of the light-emitting element 140 may be electrically connected to the second drain electrode 122d of the second transistor 122 and the fourth source electrode 124s of the fourth transistor 124 through the second contact electrode 154 and the connection electrode 134.

The first contact electrode 152 and the second contact electrode 154 may be formed of a transparent conductive material such as indium tin oxide (ITO) or indium zinc oxide (IZO). Alternatively, the first contact electrode 152 and the second contact electrode 154 may be formed of a metal, and may be formed of one or more of aluminum (Al), copper (Cu), molybdenum (Mo), titanium (Ti), chromium (Cr), nickel (Ni), tungsten (W), and an alloy thereof, for example.

As such, the display device according to the first example embodiment of the present disclosure may include the fourth transistor 124 as the connection element. Since the fourth transistor 124 has substantially the same structure and is substantially on the same plane as the first, second, and third transistors 121, 122, and 123, the connection element can be easily formed without an additional process.

Meanwhile, by providing the connection element on a different plane from the first, second, and third transistors 121, 122, and 123, a design area of a pixel circuit can be secured.

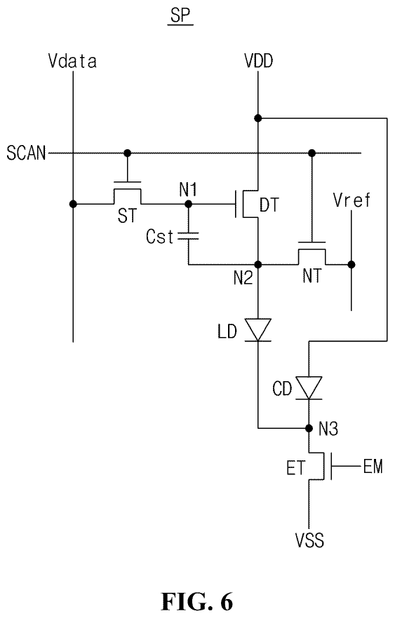

A display device according to a second example embodiment of the present disclosure will be described with reference to FIGS. 6 to 8. The display device according to the second example embodiment of the present disclosure has substantially the same or similar configuration as that of the first example embodiment, except for the connection element. The same parts as those of the first example embodiment are designated by the same or similar reference signs, and explanation for the same parts may be shortened or omitted.

FIG. 6 is an equivalent circuit diagram for a sub-pixel of a display device according to a second example embodiment of the present disclosure and will be described with reference to FIG. 1 together.

In FIG. 6, one sub-pixel SP of the display device according to the second example embodiment of the present disclosure may include a switching transistor ST, a driving transistor DT, a sensing transistor NT, a storage capacitor Cst, and a light-emitting diode LD. In addition, the sub-pixel SP may further include an emission transistor ET and a connection diode CD.

The switching transistor ST may be switched according to the gate signal SCAN and may transmit the data voltage Vdata to the first node N1. The driving transistor DT is connected to the first node N1 and a second node N2. The driving transistor DT may be switched according to a voltage of the first node N1 and may transmit the high potential voltage VDD to the second node N2. The sensing transistor NT may be switched according to the gate signal SCAN and may transmit the reference voltage Vref to the second node N2 or transmit a voltage of the second node N2 to the reference line RL. First and second capacitor electrodes of the storage capacitor Cst may be connected to the first node N1 and the second node N2, respectively. The anode of the light-emitting diode LD may be connected to the second node N2, and the cathode of the light-emitting diode LD may be connected to a third node N3.

The connection diode CD may be a connection element for connecting the third node N3 and the first power line PL1 and may transmit the high potential voltage VDD to the third node N3. Specifically, an anode of the connection diode CD may be connected to the first power line PL1 and may be supplied with the high potential voltage VDD. A cathode of the connection diode CD may be connected to the third node N3.

The connection diode CD may serve the same as the connection transistor CT of FIG. 2. The connection diode CD may be an organic diode based on an organic material, and this will be described in detail later.

As such, in the display device according to the second example embodiment of the present disclosure, by providing the connection diode CD as the connection element and forming a voltage path, the cathode voltage of the light-emitting diode LD, i.e., the voltage of the third node N3 can be controlled. Accordingly, the light-emitting diode LD can be prevented or suppressed from emitting light in a black state.

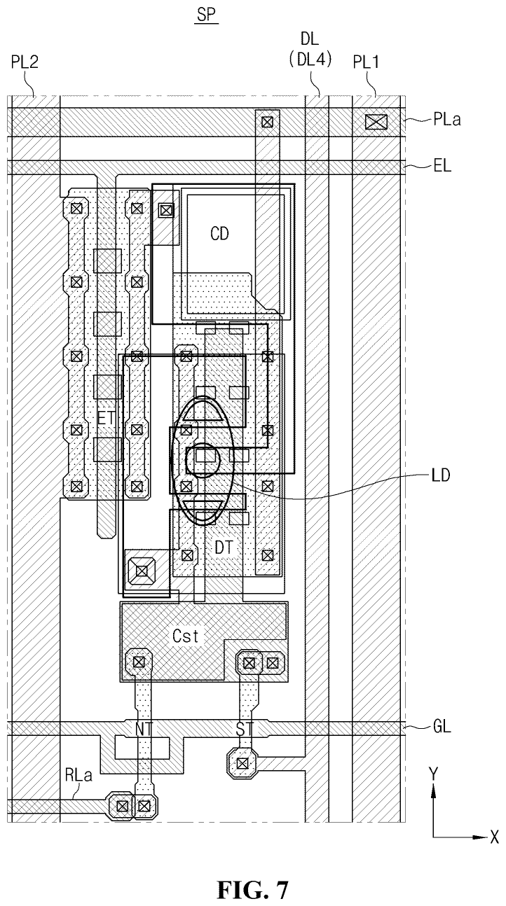

A planar configuration of the display device according to the second example embodiment of the present disclosure will be described with reference to FIG. 7.

FIG. 7 is a schematic plan view of a display device according to the second example embodiment of the present disclosure and shows one sub-pixel, which corresponds to the area A1 of FIG. 1.

In FIG. 7, the gate line GL and the emission line EL of the first direction X may cross the first power line PL1, the second power line PL2, and the data line DL of the second direction Y to define the sub-pixel SP. The switching transistor ST, the driving transistor DT, the sensing transistor NT, the emission transistor ET, the connection diode CD, the storage capacitor Cst, and the light-emitting diode LD may be provided in the sub-pixel SP.

In the first direction X, the driving transistor DT and the connection diode CD may be disposed adjacent to the emission transistor ET, and the switching transistor ST and the sensing transistor NT may be disposed adjacent to each other.

In the second direction Y, the storage capacitor Cst may be disposed between the driving and emission transistors DT and ET and the switching and sensing transistors ST and NT, and the connection diode CD may be disposed substantially between the driving transistor DT and the emission line EL. In this case, the connection diode CD may partially overlap the driving transistor DT.

Meanwhile, the light-emitting diode LD may be disposed to overlap the driving transistor DT.

The display device according to the second example embodiment of the present disclosure including the connection diode CD may operate the same as the display device of FIG. 4 according to the first example embodiment of the present disclosure including the connection transistor CT and may increase widths and areas of the driving transistor DT and the emission transistor ET compared to the display device according to the first example embodiment.

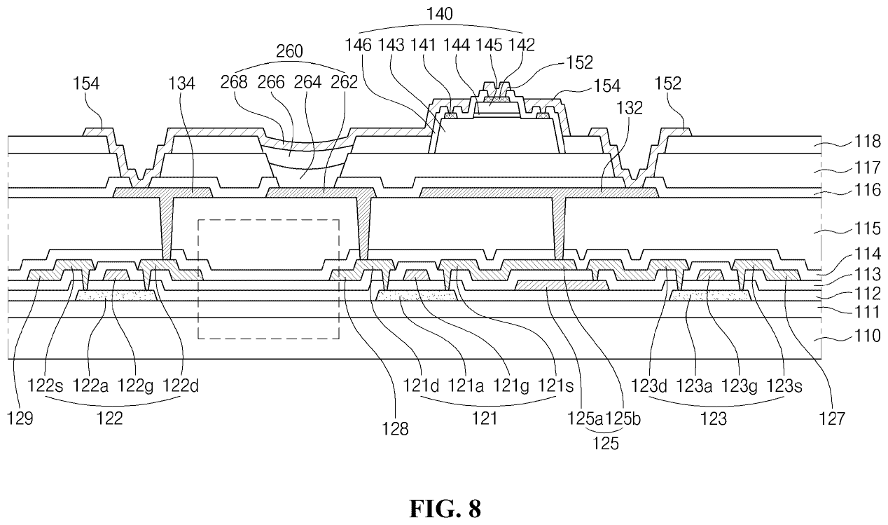

A cross-sectional configuration of the display device according to the second example embodiment of the present disclosure will be described in detail with reference to FIG. 8.

FIG. 8 is a schematic cross-sectional view of a display device according to the second example embodiment of the present disclosure and shows one sub-pixel.

In FIG. 8, the display device according to the second example embodiment of the present disclosure may include first, second, and third transistors 121, 122, and 123, a capacitor 125, an organic diode 260, and a light-emitting element 140 on a substrate 110. The light-emitting element 140 may be electrically connected to the first transistor 121 and the second transistor 122. The first transistor 121 may be electrically connected to the capacitor 125 and the third transistor 123 and electrically connected to the organic diode 260. The second transistor 122 may be electrically connected to the organic diode 260.

Namely, in the display device according to the second example embodiment of the present disclosure, the fourth transistor 124 of FIG. 5 may be omitted.

Specifically, the first, second, and third transistors 121, 122, and 123 and the capacitor 125 may be provided on the substrate 110. The first passivation layer 114 and the overcoat layer 115 may be sequentially provided on the first, second, and third transistors 121, 122, and 123 and the capacitor 125.

Next, the reflection electrode 132 and the connection electrode 134 may be provided on the overcoat layer 115. The reflection electrode 132 and the connection electrode 134 may be formed of a metal having relatively high reflectance. For example, the reflection electrode 132 and the connection electrode 134 may be formed of aluminum (Al), silver (Ag), or chromium (Cr).

The reflection electrode 132 may be electrically connected to the first transistor 121 and the capacitor 125, and the connection electrode 134 may be electrically connected to the second transistor 122. Further, the reflection electrode 132 is disposed between the first transistor 121 and the light-emitting element 140.

In addition, a first electrode 262 may be provided on the overcoat layer 115. The first electrode 262 may include the same material and be disposed on the same layer as the reflection electrode 132 and the connection electrode 134.

The first electrode 262 may partially overlap the first transistor 121 and may be electrically connected to the first transistor 121 through a contact hole provided in the first passivation layer 114 and the overcoat layer 115. In this case, the first electrode 262 may be in contact with the first drain electrode 121d of the first transistor 121 through the contact hole.

The second passivation layer 116 may be provided on the reflection electrode 132, the connection electrode 134, and the first electrode 262. The adhesive layer 117 may be provided on the second passivation layer 116. The light-emitting element 140 may be provided on the adhesive layer 117. The light-emitting element 140 may be spaced apart from the first electrode 262.

Next, the planarization layer 118 may be provided on the light-emitting element 140 and the adhesive layer 117.

The planarization layer 118 may have an opening that exposes the first electrode 262 with the second passivation layer 116 and the adhesive layer 117. A first semiconductor layer 264 and a second semiconductor layer 266 may be sequentially provided on the first electrode 262 exposed through the opening.

At least one of the first semiconductor layer 264 and the second semiconductor layer 266 may include an organic material and may be formed through a soluble process. That is, at least one of the first semiconductor layer 264 and the second semiconductor layer 266 may be an organic layer. A height of the first semiconductor layer 264 and the second semiconductor layer 266 may increase from the center to the edge.

However, embodiments of the present disclosure are not limited thereto. In other embodiments, at least one of the first semiconductor layer 264 and the second semiconductor layer 266 may include an inorganic material and may be formed through an inkjet or vacuum deposition process.

The first semiconductor layer 264 may be a p-type semiconductor layer, and the second semiconductor layer 266 may be an n-type semiconductor layer. The first semiconductor layer 264 may include at least one of a hole injection layer (HIL) and a hole transport layer (HTL). The second semiconductor layer 266 may include at least one of an electron injection layer (EIL) and an electron transport layer (ETL).

However, embodiments of the present disclosure are not limited thereto. In other embodiments, the first semiconductor layer 264 may be an n-type semiconductor layer, and the second semiconductor layer 266 may be a p-type semiconductor layer.

The first contact electrode 152 and the second contact electrode 154 may be provided on the planarization layer 118 and the light-emitting element 140. The first contact electrode 152 may be connected to the second element electrode 142 of the light-emitting element 140. The second contact electrode 154 may be connected to the first element electrode 141 of the light-emitting element. However, embodiments of the present disclosure are not limited thereto. In other embodiments, the first contact electrode 152 may be connected to the first element electrode 141 of the light-emitting element 140. The second contact electrode 154 may be connected to the second element electrode 142 of the light-emitting element 140.

Meanwhile, a second electrode 268 may be provided on the second semiconductor layer 266. The second electrode 268 may include the same material and be disposed on the same layer as the first contact electrode 152 and the second contact electrode 154. In this case, the second electrode 268 may be connected to the second contact electrode 154 and may be formed as one body with the second contact electrode 154.

The second electrode 268 may be electrically connected to the connection electrode 134 through the second contact electrode 154 and electrically connected to the second drain electrode 122d of the second transistor 122 through the second contact electrode 154 and the connection electrode 134. In addition, the second electrode 268 may be electrically connected to the first element electrode 141 of the light-emitting element 140.

The first electrode 262, the first semiconductor layer 264, the second semiconductor layer 266, and the second electrode 268 may constitute the organic diode 260, and the organic diode 260 may be the connection diode CD of FIG. 6. In this case, the first electrode 262 may be an anode, and the second electrode 268 may be a cathode. However, embodiments of the present disclosure are not limited thereto. In other embodiments, the first electrode 262 may be a cathode, and the second electrode 268 may be an anode.

The first transistor 121 may be the driving transistor DT of FIG. 6, the second transistor 122 may be the emission transistor ET of FIG. 6, the third transistor 123 may be the switching transistor ST of FIG. 6, and the capacitor 125 may be the storage capacitor Cst.

As such, the display device according to the second example embodiment of the present disclosure may include the organic diode 260 as the connection element. Since the organic diode 260 may be disposed on the different plane from the first, second, and third transistors 121, 122, and 123, the areas of the first transistor 121 and the second transistor 122, that is, the driving transistor DT and the emission transistor ET can be expanded, and it is possible to be applied to a high resolution display device.

In addition, by increasing channel widths of the driving transistor DT and the emission transistor ET, the driving current can be increased at a lower voltage, thereby reducing power consumption and shortening the on-off time of the driving and emission transistors.

By providing the connection electrode and forming the voltage path, the display device of the present disclosure can adjust the cathode voltage of the light-emitting element. Accordingly, the light-emitting element can be prevented or suppressed from emitting light in the black state, thereby improving the image quality of the display device.

In addition, by providing the organic diode as the connection element on the different plane from the transistors, the width and area of the transistors can be expanded, the display device of the present disclosure can be applied to a high resolution display device. The driving current can be increased at a lower voltage, thereby reducing power consumption and realizing low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a first transistor over the substrate and connected to a first power line;
a second transistor over the substrate and connected to a second power line;
a light-emitting element connected to the first transistor and the second transistor; and
a connection element connected to the first power line and the light-emitting element, wherein the connection element overlaps at least a part of the first transistor.

2. The display device of claim 1, wherein the connection element includes a first electrode and a second electrode, and
wherein the first electrode of the connection element is connected to the first power line, and the second electrode of the connection element is connected to a cathode of the light-emitting element.

3. The display device of claim 2, wherein a drain of the first transistor is connected to the first power line, and a source of the first transistor is connected to an anode of the light-emitting element, and
wherein a drain of the second transistor is connected to the cathode of the light-emitting element, and a source of the second transistor is connected to the second power line.

4. The display device of claim 2, wherein the first electrode is electrically connected to a drain of the first transistor, and the second electrode is electrically connected to a drain of the second transistor.

5. The display device of claim 2, wherein the connection element further includes a first semiconductor layer and a second semiconductor layer between the first electrode and the second electrode, and
wherein one of the first semiconductor layer and the second semiconductor layer is an n-type semiconductor layer and another of the first semiconductor layer and the second semiconductor layer is a p-type semiconductor layer.

6. The display device of claim 5, wherein the connection element is an organic diode in which at least one of the first semiconductor layer and the second semiconductor layer includes an organic material.

7. The display device of claim 6, wherein a height of the first semiconductor layer and the second semiconductor layer increases from a center to an edge.

8. The display device of claim 2, further comprising a reflection electrode between the first transistor and the light-emitting element,
wherein the first electrode includes a same material and is disposed on a same layer as the reflection electrode.

9. The display device of claim 8, further comprising:
a first contact electrode connected to a first element electrode of the light-emitting element; and
a second contact electrode connected to a second element electrode of the light-emitting element,
wherein the second electrode includes a same material and is disposed on a same layer as the first contact electrode and the second contact electrode.

10. The display device of claim 1, further comprising an overcoat layer between the first and second transistors and the connection element.

11. The display device of claim 1, further comprising:
a third transistor switched according to a gate signal and transmitting a data voltage to a first node;
a fourth transistor switched according to the gate signal and transmitting a reference voltage to a second node or transmitting a voltage of the second node to a reference line; and
a capacitor connected to the first node and the second node,
wherein the first transistor is connected to the first node and the second node, and the light-emitting element is connected to the second node.
